(19) United States
(12) Patent Application Publication
(10) Pub. No.: US 2022/0158011 A1
(43) Pub. Date: May 19, 2022

(54) SOLAR CELL MODULE WITH HOLES AND METHOD FOR MANUFACTURING THE SAME

(71) Applicant: KOREA PHOTONICS TECHNOLOGY INSTITUTE, Gwangju (KR)

(72) Inventors: Hyo Jin KIM, Gwangju (KR); Chae Won KIM, Daegu (KR); Gwang Ryeol PARK, Gochang-gun (KR)

(21) Appl. No.: 17/509,283

(22) Filed: Oct. 25, 2021

(30) Foreign Application Priority Data
Nov. 13, 2020 (KR) 10-2020-0151699

(51) Int. Cl. H01L 31/0392; H02S 40/22; H02S 40/44; H01L 31/18

(52) U.S. Cl. CPC H01L 31/03926; H01L 31/1892; H02S 40/44; H02S 40/22

(57) ABSTRACT

According to an embodiment, a transparent solar cell, a photovoltaic system including the transparent solar cell, and a method for manufacturing the transparent solar cell are provided. The transparent solar cell comprises a substrate, an adhesive layer formed on the substrate, a metal layer formed on the adhesive layer, a solar cell layer formed on the metal layer, and a coating layer formed on the solar cell layer. The solar cell layer and the metal layer include a plurality of holes having a predetermined diameter.

### CROSS-REFERENCE TO RELATED APPLICATION(S)

This application is based on and claims priority under 35 U.S.C. 119 to Korean Patent Application No. 10-2020-0151699, filed on Nov. 13, 2020, in the Korean Intellectual Property Office, the disclosure of which is herein incorporated by reference in its entirety.

### TECHNICAL FIELD

Embodiments of the disclosure relate to a solar cell module including holes and a method for manufacturing the same.

### DESCRIPTION OF RELATED ART

The description of the Discussion of Related Art section merely provides information that may be relevant to embodiments of the disclosure but should not be appreciated as necessarily constituting the prior art.

Recently, as the reserves of traditional fossil fuels decrease and environmental contamination worsens due to fossil fuels, interest in the use of eco-friendly alternative energy is increasing. In particular, solar cells using sunlight are spotlighted as the most promising alternative energy to replace traditional energy in the future thanks to techniques evolved through long-term research.

Solar cells are installed in locations with lots of sunlight radiations, such as buildings or transportation means. By the nature of the solar cell installed in such an open space, there is an increasing demand for transparent solar cells for aesthetic reasons.

However, conventional transparent solar cells, which transmit a certain proportion of incident light while generating electricity from the remaining light, generally has a low power generation efficiency of less than 10%. Therefore, a need exists for solar cells that provide superior power generation efficiency while having transparency.

### SUMMARY

According to an embodiment of the disclosure, there are provided a solar cell module that is transparent and may secure high power generation efficiency and a method for manufacturing the same.

According to an embodiment, a transparent solar cell comprises a substrate, an adhesive layer formed on the substrate, a metal layer formed on the adhesive layer, a solar cell layer formed on the metal layer, and a coating layer formed on the solar cell layer. The solar cell layer and the metal layer include a plurality of holes having a predetermined diameter.

According to an embodiment, an electrode pattern or a first electrode layer may be formed on the solar cell layer.

According to an embodiment, a second electrode layer may be formed on a lower end of the substrate.

According to an embodiment, the adhesive layer may be formed of platinum or gold.

According to an embodiment, the substrate may have flexible characteristics.

According to an embodiment, a method for manufacturing a transparent solar cell comprises forming a sacrificial layer, a solar cell layer, and a metal layer on a temporary substrate, forming a plurality of holes having a predetermined diameter in the solar cell layer and the metal layer, forming an adhesive layer on a substrate, forming a plurality of holes having a predetermined diameter in the adhesive layer, bonding the metal layer onto the adhesive layer, with the plurality of holes formed in the metal layer aligned with the plurality of holes formed in the adhesive layer, and separating the temporary substrate by etching the sacrificial layer.

According to an embodiment, the method may further comprise forming an electrode pattern or a first electrode layer on the solar cell layer.

According to an embodiment, the method may further comprise forming a second electrode layer on a lower end of the substrate.

According to an embodiment, the adhesive layer may be formed of platinum or gold.

According to an embodiment, the substrate may have flexible characteristics.

According to an embodiment, a photovoltaic system comprises the transparent solar cell, a first lens focusing light transmitted through the transparent solar cell, a pipe disposed in a position where the light is focused by the first lens, and a second lens changing a path of the light passing through the pipe.

According to an embodiment, the pipe may allow a fluid to be heated by sunlight to flow therein.

According to an embodiment, a photovoltaic system comprises the transparent solar cell, and a pipe disposed under the transparent solar cell to receive light passing through the transparent solar cell and heat a fluid flowing therein.

According to an embodiment, the fluid may be water.

According to an embodiment, a photovoltaic system comprises a first lens focusing incident light, the transparent solar cell, the transparent solar cell disposed in a position where the light is focused by the first lens, a second lens focusing the light transmitted through the transparent solar cell, a pipe disposed in a position where the light is focused by the first lens, and a third lens changing a path of the light passing through the pipe.

According to an embodiment, a photovoltaic system comprises a first lens focusing incident light, the transparent solar cell, the transparent solar cell disposed in a position where the light is focused by the first lens, a second lens changing a path of the light transmitted through the transparent solar cell, and a pipe disposed under the second lens to receive the light passing through the second lens and heat a fluid flowing therein.

According to the embodiments of the disclosure, it is possible to provide a solar cell module that may have high power generation efficiency although having transparency.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view illustrating a photovoltaic system according to a first embodiment of the disclosure;

FIG. 2 is a cross-sectional view illustrating a photovoltaic system according to a second embodiment of the disclosure;

FIG. 3 is a cross-sectional view illustrating a photovoltaic system according to a third embodiment of the disclosure;

FIG. 4 is a cross-sectional view illustrating a photovoltaic system according to a fourth embodiment of the disclosure;

FIG. 5 is a perspective view illustrating a solar cell module according to an embodiment of the disclosure;

FIG. 6 is a graph illustrating the absorbance for each light wavelength band introduced into water; and

FIGS. 7, 8, 9, 10, 11, 12, 13, 14, and 15 are views illustrating a method for manufacturing a solar cell module according to an embodiment of the disclosure.

### DETAILED DESCRIPTION

Various changes may be made to the present invention, and the present invention may come with a diversity of embodiments. Some embodiments of the present invention are shown and described in connection with the drawings. However, it should be appreciated that the present disclosure is not limited to the embodiments, and all changes and/or equivalents or replacements thereto also belong to the scope of the present disclosure. Similar reference denotations are used to refer to similar elements throughout the drawings. The terms “first” and “second” may be used to describe various components, but the components should not be limited by the terms. The terms are used to distinguish one component from another. For example, a first component may be denoted a second component, and vice versa without departing from the scope of the present disclosure. The term “and/or” may denote a combination(s) of a plurality of related items as listed or any of the items. It will be understood that when an element or layer is referred to as being “on,” “connected to,” “coupled to,” or “adjacent to” another element or layer, it can be directly on, connected, coupled, or adjacent to the other element or layer, or intervening elements or layers may be present. In contrast, when a component is “directly connected to” or “directly coupled to” another component, no other intervening components may intervene therebetween.

The terms as used herein are provided merely to describe some embodiments thereof, but not to limit the present disclosure. As used herein, the singular forms “a,” “an,” and “the” are intended to include the plural forms as well, unless the context clearly indicates otherwise. As used herein, the term “comprise,” “include,” or “have” should be appreciated not to preclude the presence or addability of features, numbers, steps, operations, components, parts, or combinations thereof as set forth herein.

Unless otherwise defined, all terms including technical and scientific terms used herein have the same meaning as commonly understood by one of ordinary skill in the art to which the embodiments of the present disclosure belong.

It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The components, processes, steps, or methods according to embodiments of the disclosure may be shared as long as they do not technically conflict with each other.

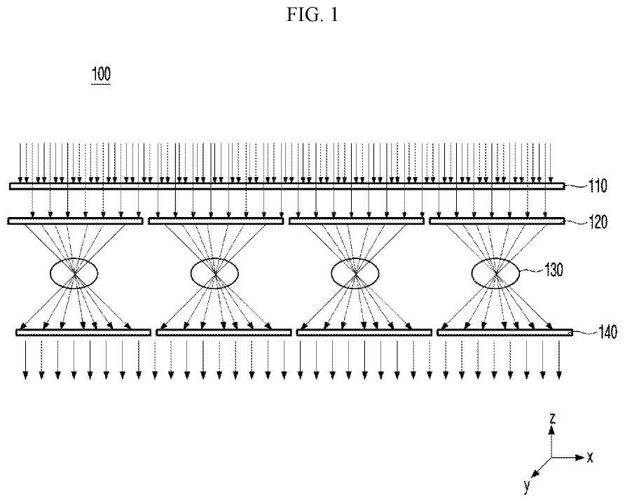

FIG. 1 is a cross-sectional view illustrating a photovoltaic system according to a first embodiment of the disclosure.

Referring to FIG. 1, a photovoltaic system 100 according to the first embodiment of the present invention includes a solar cell module 110, a first lens 120, a pipe 130, and a second lens 140.

The photovoltaic system 100 generates power using incident sunlight while simultaneously heating the fluid using solar heat. The photovoltaic system 100 transmits a portion of the sunlight to grow animals or plants in a space under (in the -x-axis direction or the direction in which sunlight is incident) the photovoltaic system 100, rather than generating photovoltaic power using the whole of the incident sunlight. Since the conventional photovoltaic panel absorbs all incident light, the light could not reach the space under the photovoltaic panel. Thus, the space under the photovoltaic panel was an environment where animals and plants could not grow. In contrast, the photovoltaic system 100 has a structure in which only a portion of sunlight may be used for solar power generation (photovoltaic power generation), and the rest heats the fluid while reaching the animals and plants under the system 100. A detailed structure of the photovoltaic system 100 is described below. The solar cell module 110 may be disposed at the top (in the direction in which sunlight is incident) of the system 100 and generates electrical energy from incident sunlight. The solar cell module 110 does not need to have transparency due to its own material. Since a solar cell whose material itself has transparency transmit a certain proportion of sunlight and generate electrical energy from the remainder, its power generation efficiency is relatively significantly reduced. Accordingly, according to an embodiment, the solar cell module 110 is not formed of a material having transparency but secures transparency by including a plurality of holes with a tiny size (diameter). As light passes through the holes formed in the solar cell module 110, the solar cell module 110 may secure transparency. The solar cell module 110 may be formed of a group 3(III)-5(V) compound having excellent electrical energy generation efficiency but, without being limited thereto, the solar cell module 110 may be formed of other materials, such as silicon

(Si), cadmium telluride (CdTe), or copper indium gallium diselenide (CIGS).

Further, as the solar cell module 110 includes a plurality of layers having different energy band gaps, the solar cell module 110 has relatively high power generation efficiency.

The first lens 120 focuses the sunlight passing through the solar cell module 110. The first lens 120 is positioned under the solar cell module 110 along the light path and collect (or focus) the sunlight passing through the holes in the solar cell module 110 to a pipe 130. Accordingly, the fluid flowing in the pipe 130 may be heated.

The pipe 130 is disposed in a position where light is collected (or focused) by the first lens 120. A fluid having a low specific heat and a high heat capacity flows in the pipe 130. For example, this fluid may be water. When water flows through the pipe 130, the pipe 130 is heated by receiving sunlight focused by the first lens 120. As the pipe 130 is heated, the temperature of the water rises and the water is heated. Heated water may be used for heating or hot water purposes. In this case, if water is used as the fluid flowing in the pipe 130, the following effects may be obtained. The absorbance for each wavelength band of water is shown in FIG. 6.

FIG. 6 is a graph illustrating the absorbance for each light wavelength band introduced into water.

Referring to FIG. 6, water absorbs a significant amount of light in the infrared band (after 700 nm) but hardly (not at all) absorbs light in the visible or ultraviolet band. Even if the light that has passed through the holes in the solar cell module 110 passes through the fluid through the pipe 130, the light in the visible and ultraviolet bands may be transmitted without being absorbed. Accordingly, the light in the visible and ultraviolet bands may pass through the pipe 130 and travel on along the path. As such, the photovoltaic system 100 may allow the animals or plants to grow by the visible or ultraviolet bands of light reaching the space thereunder while generating power using sunlight and solar heat. Therefore, the photovoltaic system 100 may be deployed without any trouble even in places where animals or plants grow, generating power.

Referring back to FIG. 1, the second lens 140 is disposed under the pipe 130. The second lens 140 changes the path of light incident thereon according to the type of animals and plants positioned under the system 100. As long as it is a type that may receive light of a certain intensity, the second lens 140 may be implemented as a collimator lens to change the incident light into parallel light. The second lens 140 changes the light path to allow the animals or plants under the system (in the -z-axis direction) to wholly receive the sunlight (in the visible and ultraviolet bands). If it is desirable to receive light of a certain intensity or less, the second lens 140 may be implemented as a dispersion lens to disperse the incident light. The second lens 140 disperses the light to prevent light of excessive intensity from being irradiated to animals and plants.

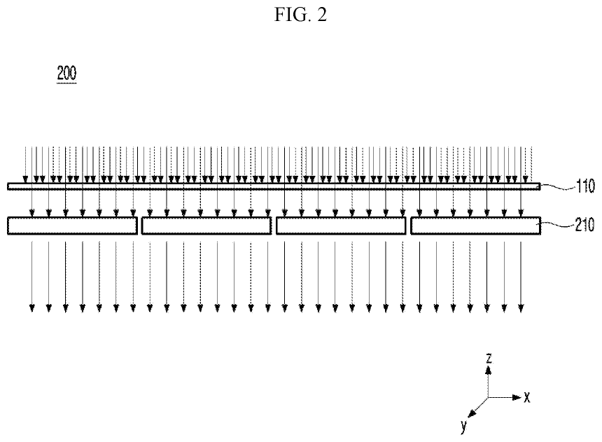

FIG. 2 is a cross-sectional view illustrating a photovoltaic system according to a second embodiment of the disclosure.

Referring to FIG. 2, a photovoltaic system 200 according to the second embodiment of the present invention includes a solar cell module 110 and a pipe 210.

The same solar cell module 110 as the solar cell module 110 in the photovoltaic system 100 may be disposed in the same position.

The pipe 210 is disposed under (in the -z-axis direction) the solar cell module 110. The pipe 210 may be disposed under the solar cell module 110 without a separate lens disposed therebetween. The pipe 210 may have a predetermined area on an xy plane (a plane perpendicular to the direction in which the light is incident) and be heated by receiving the light passing through the solar cell module 110. The fluid flowing in the pipe 210 may be heated and may be used for heating or hot water purposes.

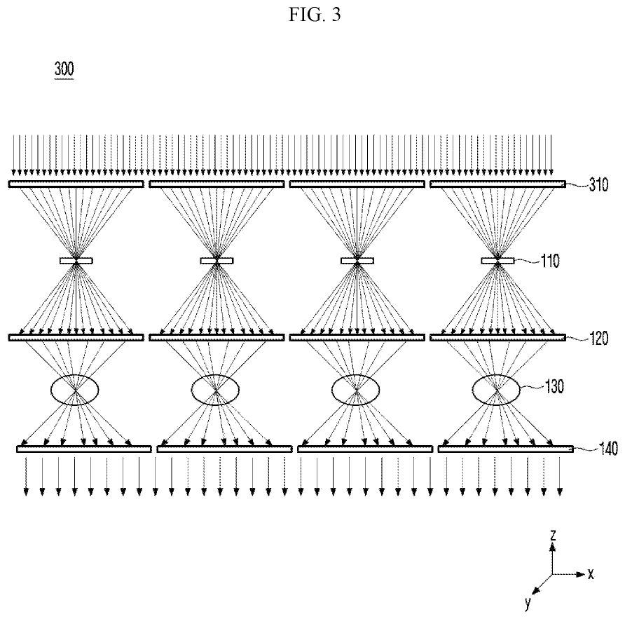

FIG. 3 is a cross-sectional view illustrating a photovoltaic system according to a third embodiment of the disclosure.

Referring to FIG. 3, a photovoltaic system 300 according to the third embodiment of the present invention may include a third lens 310, a solar cell 110, a first lens 120, a pipe 130, and a second lens 140. The first lens 120, the pipe 130, and the second lens 140 in the photovoltaic system 300 may operate in the same way as those in the photovoltaic system 100. However, the third lens 310 is disposed over the solar cell 110 (ahead of the solar cell in the +z-axis direction or in the direction in which the light is incident) to focus the sunlight incident on the photovoltaic system 300.

Unlike in the photovoltaic system 100, in the photovoltaic system 300, the solar cell 110 is disposed in a position where the third lens 310 focuses sunlight. Since the third lens 310 focuses sunlight, the solar cell 110 advantageously need not be as large as that of the photovoltaic system 100.

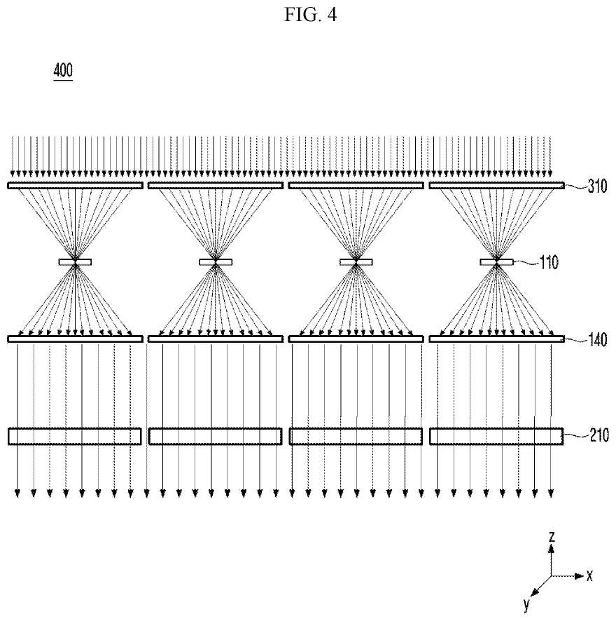

FIG. 4 is a cross-sectional view illustrating a photovoltaic system according to a fourth embodiment of the disclosure.

Referring to FIG. 4, a photovoltaic system 400 according to the fourth embodiment of the present invention includes a third lens 310, a solar cell 110, a second lens 140, and a pipe 210.

The third lens 310, the solar cell 110, and the second lens 140 in the photovoltaic system 400 may operate in the same way as those in the photovoltaic system 300.

The pipe 210 is disposed under the second lens 140 (in the -z-axis direction). The pipe 210 may have a predetermined area on an xy plane (a plane perpendicular to the direction in which the light is incident) and be heated by receiving the light passing through the second lens 140. The fluid flowing in the pipe 210 may be heated and may be used for heating or hot water purposes.

The pipe 210 in the photovoltaic system 400 operates in the same manner as that in the photovoltaic system 200.

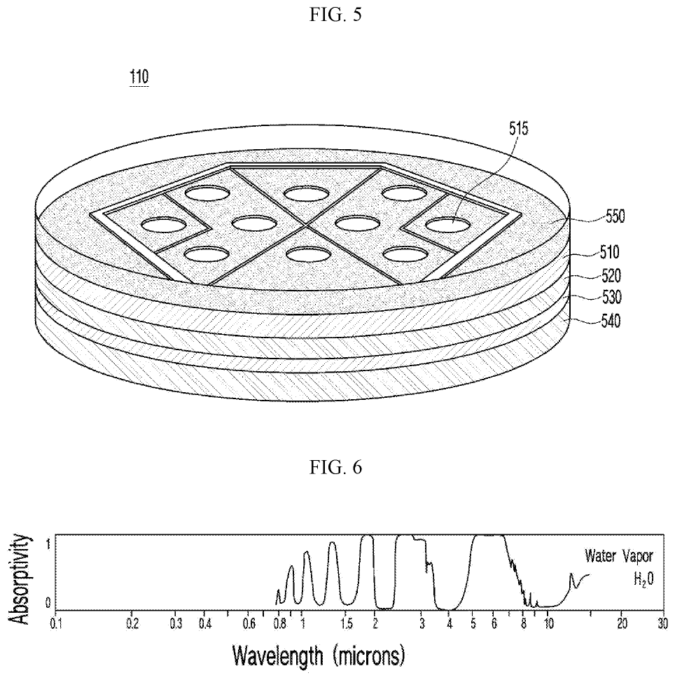

FIG. 5 is a perspective view illustrating a solar cell module according to an embodiment of the disclosure.

Referring to FIG. 5, according to an embodiment, a solar cell module 110 includes a solar cell 510, a metal layer 520, an adhesive layer 530, a substrate 540, a coating layer 550, and an electrode layer (not shown).

The solar cell 510 receives sunlight and generates electrical energy. The solar cell 510 includes a plurality of holes 515 having a diameter of nanometers to micrometers. In order for the solar cell module 110 to secure transparency, the solar cell 510 may include the plurality of holes 515. As sunlight may pass through the holes 515 of the solar cell 510, the solar cell module 110 may secure transparency.

The metal layer 520 IS disposed under the solar cell 510 and reflects the light transmitted through the solar cell 510 to the solar cell 510. To enhance the power generation efficiency of the solar cell 510, the metal layer 520 reflects the light from under the solar cell 510 to the solar cell 510. As the metal layer 520 reflects light, the metal layer 520 may include holes having the same size as the holes of the solar cell 510 in the same positions as the holes of the solar cell 510. The metal layer 520 may be a p-type metal.

The adhesive layer 530 may be disposed between the substrate 540 and the metal layer 520 to enhance adhesion of the metal layer 520 to the substrate 540. The adhesive layer 530 may be formed of platinum (Pt) and gold (Au) and may thus enhance adhesion of the metal layer 520 to the substrate 540.

The substrate 540 supports the components in the solar cell module 110 at the lowermost end. The substrate 540 may be formed in a predetermined thickness or less to have flexibility.

The coating layer 550 may be deposited on the solar cell 510, protecting the solar cell 510 from the outside and enhancing the entrance of light to the solar cell 510. The coating layer 550 may be an anti-reflection coating layer to facilitate entrance of light to the solar cell 510.

An electrode layer (not shown) may be formed on each of the upper end of the solar cell 510 and the lower end of the substrate 540, transferring the electrical energy generated from the solar cell 510 to the outside. One electrode layer (not shown) may be deposited as an electrode pattern on the upper end of the solar cell 510 or may be stacked, as a transparent electrode, on the upper end of the solar cell 510. After the electrode layer (not shown) is deposited or stacked on the upper end of the solar cell 510, the coating layer 550 may be deposited to include the electrode layer (not shown). Another electrode layer (not shown) is formed on the lower end of the substrate 540.

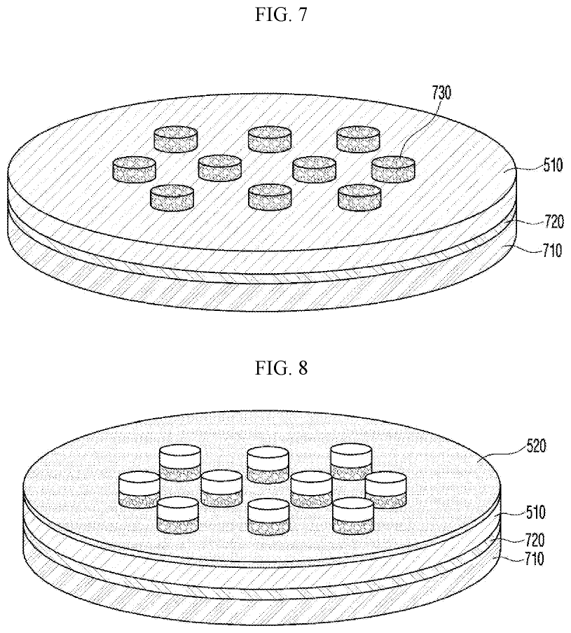

The so-structured solar cell module 110 is manufactured through the process of FIGS. 7 to 15.

FIGS. 7, 8, 9, 10, 11, 12, 13, 14, and 15 are views illustrating a method (or process) for manufacturing a solar cell module according to an embodiment of the disclosure. The process of

FIGS. 7 to 15 may be performed by a solar cell module manufacturing device.

Referring to FIG. 7, a sacrificial layer 720 and a solar cell 510 are stacked on a temporary substrate 710. Photoresists 730 with the same diameter as the holes to be formed in the solar cell 510 and a metal layer 520 are stacked, over the stacked solar cell 510, in the positions of the holes.

Referring to FIG. 8, a metal layer 520 is stacked on the solar cell 510 and the photoresists 730.

Referring to FIG. 9, the stacked photoresists 730 are etched. Etching may be performed by an etchant or may be performed dry etching. As the photoresists 730 may be etched, the metal layer 520 deposited on the photoresists 730 is also removed. Accordingly, holes 910 are formed in the metal layer 520.

After the holes 910 are formed in the metal layer 520, holes are additionally formed in the solar cell 510. Accordingly, holes are formed in the metal layer 520 and the solar cell 510 in the same positions and in the same size.

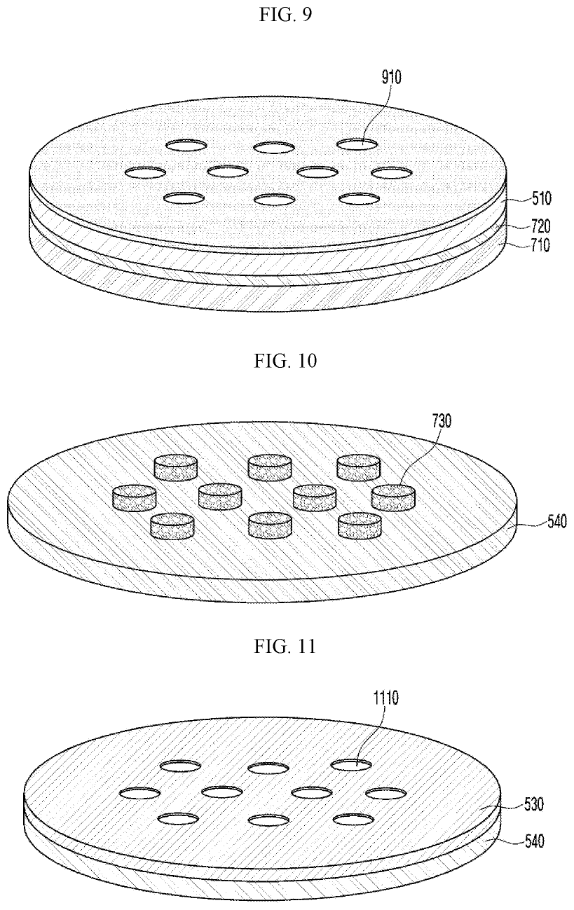

Referring to FIG. 10, as a separate step, photoresists 730 are stacked, on the substrate 540, in the same size and positions as the holes formed in the metal layer 520 and the solar cell 510.

Thereafter, referring to FIG. 11, the same holes 1110 are formed in the adhesive layer 530 by performing the same process as in FIGS. 8 and 9.

Referring to FIG. 12, each layer stacked on the temporary substrate 710 by the process of FIGS. 7 to 9 and the adhesive layer 530 stacked on the substrate 540 are bonded to each other. In this case, the bonding is performed, with the adhesive layer 530 and the metal layer 520 facing each other. In other words, after bonding, the adhesive layer 530, the metal layer 520, the solar cell 510, the sacrificial layer 720, and the temporary substrate 710 are stacked on the substrate 540 in the order thereof.

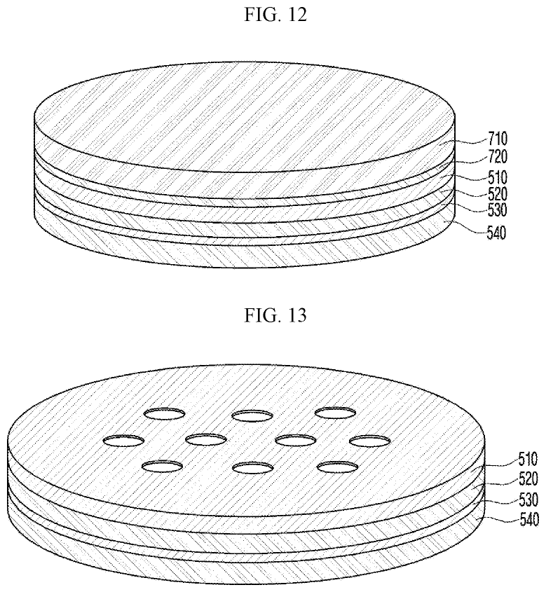

Referring to FIG. 13, the sacrificial layer 720 is etched to separate the temporary substrate 710 from the remaining layers. Since the process of FIGS. 8 and 9 and the process of FIG. 9 have been performed, holes of the same size are formed, in the same positions, in the solar cell 510, the metal layer 520, and the adhesive layer 530.

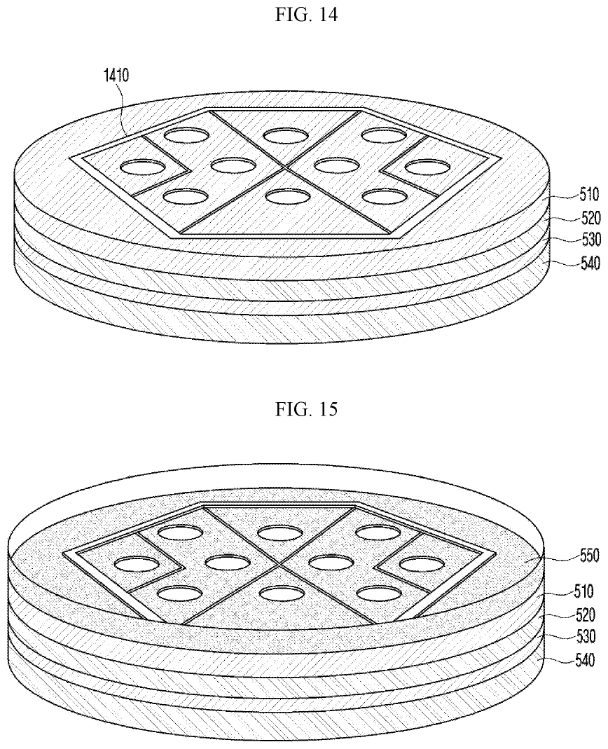

Referring to FIG. 14, an electrode layer is formed on the solar cell 510. As shown in FIG. 14, an electrode pattern 1410 may be deposited on the upper surface of the solar cell 510, or a transparent electrode (such as indium tin oxide (ITO) or aluminum-doped zinc oxide (AZO)) may be stacked on the upper surface of the solar cell 510. Although not shown in FIG. 14, an electrode may also be disposed on the lower end of the substrate 540 in the same manner.

Referring to FIG. 15, a coating layer 550 is stacked on the solar cell 510 on which the electrode layer is formed.

The above-described embodiments are merely examples, and it will be appreciated by one of ordinary skill in the art various changes may be made thereto without departing from the scope of the present invention. Accordingly, the embodiments set forth herein are provided for illustrative purposes, but not to limit the scope of the present invention, and should be appreciated that the scope of the present invention is not limited by the embodiments. The scope of the present invention should be construed by the following claims, and all technical spirits within equivalents thereof should be interpreted to belong to the scope of the present invention.

What is claimed is:

1. A transparent solar cell, comprising:
a substrate;
an adhesive layer formed on the substrate;
a metal layer formed on the adhesive layer;
a solar cell layer formed on the metal layer; and
a coating layer formed on the solar cell layer, wherein the solar cell layer and the metal layer include a plurality of holes having a predetermined diameter.

2. The transparent solar cell of claim 1, wherein an electrode pattern or a first electrode layer is formed on the solar cell layer.

3. The transparent solar cell of claim 2, wherein a second electrode layer is formed on a lower end of the substrate.

4. The transparent solar cell of claim 1, wherein the adhesive layer is formed of platinum or gold.

5. The transparent solar cell of claim 1, wherein the substrate has flexible characteristics.

6. A method for manufacturing a transparent solar cell, the method comprising:
forming a sacrificial layer, a solar cell layer, and a metal layer on a temporary substrate;
forming a plurality of holes having a predetermined diameter in the solar cell layer and the metal layer;
forming an adhesive layer on a substrate;
forming a plurality of holes having a predetermined diameter in the adhesive layer;
bonding the metal layer onto the adhesive layer, with the plurality of holes formed in the metal layer aligned with the plurality of holes formed in the adhesive layer; and
separating the temporary substrate by etching the sacrificial layer.

7. The method of claim 6, further comprising forming an electrode pattern or a first electrode layer on the solar cell layer.

8. The method of claim 7, further comprising forming a second electrode layer on a lower end of the substrate.

9. The method of claim 6, wherein the adhesive layer is formed of platinum or gold.

10. The method of claim 6, wherein the substrate has flexible characteristics.

11. A photovoltaic system, comprising:
a transparent solar cell; and
a pipe disposed under the transparent solar cell to receive light passing through the transparent solar cell and heat a fluid flowing therein, wherein the transparent solar cell includes:
a substrate;
an adhesive layer formed on the substrate;
a metal layer formed on the adhesive layer;
a solar cell layer formed on the metal layer; and
a coating layer formed on the solar cell layer, wherein the solar cell layer and the metal layer include a plurality of holes having a predetermined diameter.

12. The photovoltaic system of claim 11, further comprising a first lens focusing light transmitted through the transparent solar cell.

13. The photovoltaic system of claim 12, wherein the pipe is disposed in a position where the light is focused by the first lens.

14. The photovoltaic system of claim 11, further comprising a second lens changing a path of the light passing through the pipe.

15. The photovoltaic system of claim 11, further comprising a third lens focusing light incident on the transparent solar cell.

16. The photovoltaic system of claim 15, wherein the transparent solar cell is disposed in a position where the third lens focuses the light.
